(19) United States
(12) Patent Application Publication
(10) Pub. No.: US 2007/0168809 A1
(43) Pub. Date: Jul. 19, 2007

(54) Systems and methods for LBIST testing using commonly controlled LBIST satellites

(76) Inventors: Naoki Kiryu, Tokyo (JP); Nathan Paul Chelstrom, Austin, TX (US); Mack Wayne Riley, Austin, TX (US); Louis B. Bushard, Rochester, MN (US)

Correspondence Address: LAW OFFICES OF MARK L. BERRIER, 3811 BEE CAVES ROAD, SUITE 204, AUSTIN, TX, 78746, US

(21) Appl. No.: 11/199,972

(22) Filed: Aug. 9, 2005

(51) Int. Cl. G01R 31/28

(52) U.S. Cl. 714/733

(57) ABSTRACT

Systems and methods for performing logic built-in self-tests (LBISTs) in which an LBIST controller provides control signals to multiple LBIST satellites that are co-located with different functional blocks of the device under test, such as processor cores in a multiprocessor integrated circuit. Because the data paths for each satellite are shorter than data paths in conventional LBIST architectures, fewer latches are needed to synchronize the delivery of data to scan chains in the satellites. In one embodiment, each satellite includes a pseudorandom bit pattern generator (PRPG,) scan chains and a multiple-input signature register (MISR). In one embodiment, the LBIST circuitry also includes a control scan chain that is coupled to each of the LBIST satellites and configured to scan data into and out of the LBIST satellites.

### BACKGROUND

1. Field of the Invention

The invention relates generally to the testing of electronic circuits, and more particularly to systems and methods for performing logic built-in self-tests (LBISTs) using circuitry that employs multiple LBIST satellites which are controlled by a single LBIST controller.

2. Related Art

Digital devices are becoming increasingly complex. As the complexity of these devices increases, there are more and more chances for defects that may impair or impede proper operation of the devices. The testing of these devices is therefore becoming increasingly important.

Testing of a device may be important at various stages, including in the design of the device, in the manufacturing of the device, and in the operation of the device. Testing at the design stage ensures that the

design is conceptually sound. Testing during the manufacturing stage may be performed to ensure that the timing, proper operation and performance of the device are as expected. Finally, after the device is manufactured, it may be necessary to test the device to determine whether it contains any defects that prevent it from operating properly during normal usage.

Ideally, it would be possible and/or practical to test the device for every possible defect. Because of the complexity of most devices, however, it would be prohibitively expensive to take the deterministic approach of testing every possible combination of inputs to each logic gate and states of the device. A more practical approach applies pseudorandom input test patterns to the inputs of the different logic gates.

The outputs of the logic gates are then compared to the outputs generated by a “good” device (one that is known to operate properly) in response to the same pseudorandom input test patterns. The more input patterns that are tested, the higher the probability that the logic circuit being tested operates properly (assuming there are no differences between the results generated by the two devices.)

This non-deterministic approach can be implemented using logic built-in self-test (LBIST) techniques. For example, one LBIST technique (which is referred to as a STUMPS architecture) involves incorporating latches between portions of the logic being tested (the target logic,) loading these latches with pseudorandom bit patterns and then capturing the bit patterns that result from the propagation of the pseudorandom data through the target logic. Conventionally, bit patterns are produced by a single pseudorandom pattern generator (PRPG) and are then serially loaded (scanned) into chains of the latches (scan chains.) The bit patterns resulting from propagation of the pseudorandom data through the target logic are then scanned out of the scan chains and are processed by a single multiple-input signature register (MISR.)

While this testing approach can be very effective, it does have some drawbacks. Because the distance from the PRPG to each scan chains may be different, it is necessary to insert latches into the data paths between the PRPG and the scan chains in order to ensure that the pseudorandom bit patterns are scanned into the scan chains at the same time. The shorter the data path, the more latches need to be inserted in the data path. Similarly, it is necessary to insert latches into the data paths from the scan chains to the MISR. The number of latches that have to be inserted in the data paths increases as the scan speed increases (which is desirable in order to decrease the time required for the LBIST testing.) The number of latches that are necessary also increases as the number of scan chains increases (which may be necessary because of increasing numbers of logic gates in modern devices.)

Because increasing scan shift speeds and increasing complexity of devices under test results in a need for larger numbers of latches in the scan chain data paths, increasing amounts of chip space are needed to implement conventional STUMPS LBIST architectures. It would therefore be desirable to provide systems and methods for implementing LBIST testing that require less chip space.

### SUMMARY OF THE INVENTION

One or more of the problems outlined above may be solved by the various embodiments of the invention. Broadly speaking, the invention comprises systems and methods for performing logic built-in self-tests (LBISTs) in digital circuits. In one embodiment, an LBIST controller provides control signals to multiple LBIST satellites that are distributed throughout the device under test.

Each of the LBIST satellites includes a pseudorandom bit pattern generator (PRPG,) scan chains and a multiple-input signature register (MISR). Latches are inserted in the control paths between the LBIST controller and the LBIST satellites to synchronize receipt of the control signals by the satellites, but no additional latches are needed for synchronization in the data paths.

One embodiment comprises a system including multiple LBIST satellites that are coupled to a common LBIST controller. Each of the LBIST satellites is configured to perform LBIST testing on a different portion of functional logic of the device under test. The LBIST satellites perform the LBIST testing according to control signals that are received from the common LBIST controller. Because the data paths for bit patterns processed by each LBIST satellite are contained within the LBIST satellite, latches are needed in the data paths to synchronize the delivery of the data to the satellite's scan chains and to the MISR following the scan chains. In one embodiment, the LBIST is implemented in a multiprocessor integrated circuit and each of the processor cores within the multiprocessor has a corresponding LBIST satellite co-located with it. Other LBIST satellites are co-located with other functional blocks of the multiprocessor chip. In this embodiment, a single LBIST controller is coupled to each LBIST satellite by one or more control lines, and the control lines to each satellite have the same number of synchronization latches so that the control signals are delivered to each satellite at the same time. In one embodiment, the LBIST circuitry also includes a control scan chain that is coupled to each of the LBIST satellites and configured to scan data into and out of the LBIST satellites.

An alternative embodiment comprises a method including generating LBIST control signals in an LBIST controller, conveying the LBIST control signals from the LBIST controller to multiple LBIST satellites, and performing LBIST testing in each of the LBIST satellites according to the LBIST control signals. Because each satellite needs to synchronize only a portion of all of the data paths, fewer synchronization latches are needed in the data paths as compared to a conventional LBIST system. In one embodiment, the LBIST control signals are delivered to LBIST satellites that are co-located with processor cores and other functional blocks in a multiprocessor integrated circuit. In one embodiment, the method also includes scanning information into and out of the LBIST satellites using a control scan chain that couples the components of successive LBIST satellites.

Numerous additional embodiments are also possible.

### BRIEF DESCRIPTION OF THE DRAWING

Other objects and advantages of the invention may become apparent upon reading the following detailed description and upon reference to the accompanying drawings.

FIG. 1 is a functional block diagram illustrating the principal of operation of a simple STUMPS-type LBIST system.

FIG. 2 is a functional block diagrams illustrating the structure of a conventional LBIST system having a STUMPS architecture.

FIG. 3 is a functional block diagram illustrating an LBIST satellite architecture in accordance with one embodiment.

FIG. 4 is a diagram illustrating the positioning of an LBIST controller and LBIST satellites in accordance with one embodiment.

FIG. 5 is a diagram illustrating the structure of the LBIST controller and satellites in more detail in accordance with one embodiment.

FIG. 6 is a timing diagram illustrating the delay between the generation of control signals by the LBIST controller and the receipt of the signals by the LBIST satellites in accordance with the embodiment of FIG. 5.

While the invention is subject to various modifications and alternative forms, specific embodiments thereof are shown by way of example in the drawings and the accompanying detailed description. It should be understood, however, that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF PREFERRED EMBODIMENTS

One or more embodiments of the invention are described below. It should be noted that these and any other embodiments described below are exemplary and are intended to be illustrative of the invention rather than limiting.

As described herein, various embodiments of the invention comprise systems and methods for performing logic built-in self-tests (LBISTs) in digital circuits. In one embodiment, LBIST circuitry is implemented in a device such as an integrated circuit. Rather than having a conventional STUMPS LBIST structure which is used to test all of the target logic, the LBIST circuitry includes multiple LBIST satellites that are coupled to a single LBIST controller.

In this embodiment, each LBIST satellite includes a PRPG, multiple scan chains and a MISR. The PRPG in each satellite generates pseudorandom bit patterns that are loaded into the satellite's scan chains. After the pseudorandom bit patterns are propagated through the corresponding portion of the target logic, they are captured in the scan chains and are then unloaded into the satellite's MISR.

Each LBIST satellite receives control signals from a common LBIST controller. The control signals include

function and scan shift signals. These signals are distributed to each of the LBIST satellites via control lines that include latches to synchronize receipt of the signals by each of the LBIST satellites. Because the PRPG and MISR of each satellite can be positioned in close proximity to the scan chains, relatively few synchronization latches are needed in the control paths. Few, if any, synchronization latches are needed in the data paths.

The various embodiments of the invention may provide a number of advantages over conventional systems. For example, although the control lines require latches to synchronize the control signals, far fewer latches are necessary to synchronize the control paths than would be necessary to synchronize the data paths in a conventional STUMPS architecture. This advantage becomes more pronounced as the scan shift speed increases, and as the number of scan chains increases.

Various embodiments of the invention will be described below. Primarily, these embodiments will focus on implementations of an LBIST architecture within an integrated circuit. It should be noted that these embodiments are intended to be illustrative rather than limiting, and alternative embodiments may be implemented in BIST architectures other than the specific architecture described in detail below, and may also be implemented in circuits whose components are not strictly limited to logic components (e.g., AND gates, OR gates, and the like). Many such variations will be apparent to persons of ordinary skill in the art of the invention and are intended to be encompassed by the appended claims.

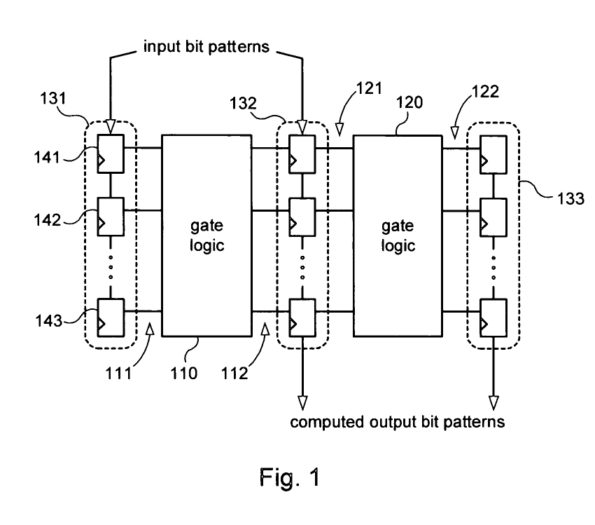

Referring to FIG. 1, a functional block diagram illustrating the principal of operation of a simple STUMPS-type LBIST system is shown. The LBIST system is incorporated into an integrated circuit. In this figure, the functional logic of the integrated circuit includes a first portion 110 and a second portion 120. Functional logic 110 is, itself, a logic circuit having a plurality of inputs 111 and a plurality of outputs 112. Similarly, functional logic 120 forms a logic circuit having a plurality of inputs 121 and a plurality and outputs 122. Functional logic 110 is coupled to functional logic 120 so that, in normal operation, outputs 112 of functional logic 110 serve as inputs 121 to functional logic 120.

Each of the inputs to, and outputs from, functional logic 110 and 120 is coupled to a scan latch. The set of scan latches 131 that are coupled to inputs 111 of functional logic 110 forms one is referred to as a scan chain. The latches are serially coupled together so that bits of data can be shifted through the latches of a scan chain. For example, a bit may be scanned into latch 141, then shifted into latch 142, and so on, until it reaches latch 143. More specifically, as this bit is shifted from latch 141 into latch 142, a second bit is shifted into latch 141. As a bit is shifted out of each latch, another bit is shifted into the latch. In this manner, a series of data bits can be shifted, or scanned, into the set of latches in scan chain 131, so that each latch stores a corresponding bit. Data can likewise be scanned into the latches of scan chain 132.

Just as data can be scanned into the latches of a scan chain (e.g., 131,) data can be scanned out of the latches of a scan chain. As depicted in FIG. 1, the latches of scan chain 132 are coupled to the outputs of functional logic 110. Each of these latches can store a corresponding bit than his output by functional logic 110. After these output bits are stored in the latches of scan chain 132, the output data bits can be shifted through the series of latches and provided as an output bit stream. Data can likewise be scanned out of the latches of scan chain 133. It should be noted that the structure illustrated in FIG. 1 does not show data being scanned into scan chain 133, or data being scanned out of scan chain 131. Alternative embodiments may be configured to scan data in and out of these scan chains.

The LBIST system of FIG. 1 operates basically as follows. Pseudorandom bit patterns are generated and are scanned into the scan chains (131, 132) that are coupled to the inputs of functional logic 110 and 120. The pseudorandom bit patterns that are stored in scan chains 131 and 132 are then propagated through the corresponding functional logic. That is, the bit pattern in scan chain 131 is propagated through functional logic 110, while the bit pattern in scan chain 132 is propagated through functional logic 120. Functional logic 110 and 120 process the inputs and generate a corresponding set of outputs. These outputs are captured (stored) in the scan chains (132 and 133) that are coupled to the outputs of the functional logic. The output bit patterns stored in scan chains 132 and 133 are then scanned out of these scan chains.

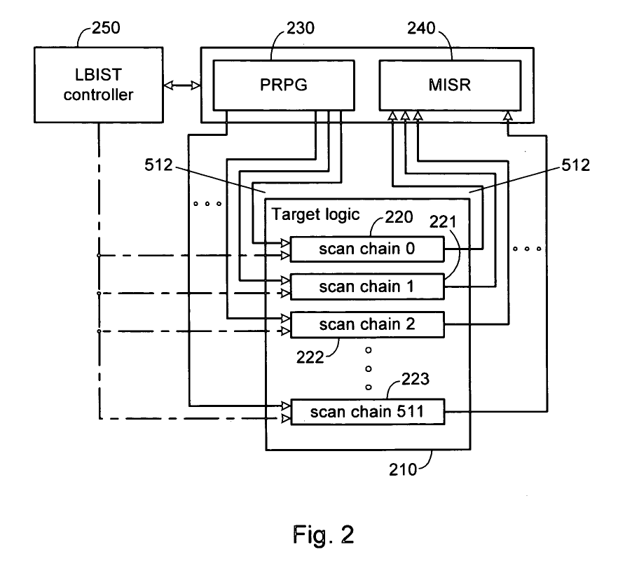

Referring to FIG. 2, a functional block diagrams illustrating the structure of a conventional LBIST system having a STUMPS architecture is shown. The LBIST system is implemented in a device that includes target logic 210. A plurality of scan chains 220-223 is interposed with the components of target logic 210. That is, the scan chains are positioned between portions of the target logic, so that each portion of the target logic receives its inputs from a first one of the scan chains and provides its outputs to a succeeding one of the scan chains as illustrated in FIG. 1. While only four scan chains are explicitly depicted in the figure, there are 512 scan chains in the illustrated system, as indicated by the 512-bit-wide data paths.

Each of scan chains 220-223 is coupled to pseudorandom pattern generator (PRPG) 230 and is configured to receive pseudorandom bit patterns that are generated by PRPG 230. As these bit patterns are scanned into scan chains 220-223 from PRPG 230, the bits that were previously stored in the scan chains are scanned out and provided to multiple input signature register (MISR) 240. The data paths in the figure are shown by solid lines. As noted above, there are 512 data paths, each extending from the PRPG to one of the scan chains, and from the scan chain to the MISR. The operation of PRPG 230, scan chains 220-223 and MISR 240 are controlled by signals received from LBIST controller 250. The control paths in the figure are shown by dashed lines.

In this system, LBIST controller 250 controls a single PRPG 230 and a single MISR 240. During an initialization phase, LBIST controller 250 prepares the components of the system for LBIST operation. For example, it may reset various components (e.g., MISR 240,) provide a seed for PRPG 230, set values in registers, and so on. If the test cycles begin with a functional phase, LBIST controller 250 may need to scan a first set of pseudorandom bit patterns into scan chains 220-223. Subsequently, in a functional phase, LBIST controller 250 controls the propagation of the pseudorandom bit patterns through the target logic. Then, in a scan shift phase, LBIST controller 250 controls the LBIST components to scan bit patterns out of the scan chains (at the same time new bit patterns are scanned into the scan chains) an into MISR 240. LBIST controller 250 repeats this to cause execution of some number of test cycles. The resulting signature value in MISR 240 can then be compared with a corresponding signature in a good device to determine whether the device under test functioned properly during the LBIST testing.

Because the scan chains of the LBIST system provide inputs to the components of the target logic and also capture the outputs of these components, the scan chains are physically distributed throughout the target logic. Since the conventional LBIST architecture shown in FIG. 2 uses a single PRPG to generate the pseudorandom bit patterns that are loaded into the scan chains, it is necessary to distribute these bit patterns to the different physical locations of the scan chain inputs. The data paths through which the bit patterns are provided to the scan chains may have different lengths because of the different locations of the scan chains. Consequently, is necessary to insert latches in the data paths in order to synchronize the arrival of the bit patterns at each of the scan chains. These latches may be referred to herein as synchronization latches. Synchronization latches may also be necessary to synchronize signals on the control paths.

The number of synchronization latches that are needed in each data path corresponds essentially to the length of the longest data path. The longer the path, the more synchronization latches are necessary. The number of synchronization latches that are needed also varies with the rate of the data signals. Thus, if the rate at which data is shifted into the scan chains (i.e., the scan shift rate) doubles, twice as many synchronization latches will be needed. Because the pseudorandom bit patterns are distributed in the system of FIG. 2 from a single PRPG, the data paths can be lengthy, so the number of synchronization latches that are needed can be very large. To make matters worse, the number of synchronization latches increases with scan shift speed and the number of scan chains, both of which are otherwise desirable.

In one embodiment of the present invention, the number of synchronization latches that are needed is reduced by reducing the lengths of the data paths. This is accomplished by partitioning the PRPG, scan chains and MISR to form LBIST satellites. Each of the individual LBIST satellites is similar in structure to the corresponding components of the conventional system, but each is designed to test only a portion of the target logic, and each is controlled by a common LBIST controller.

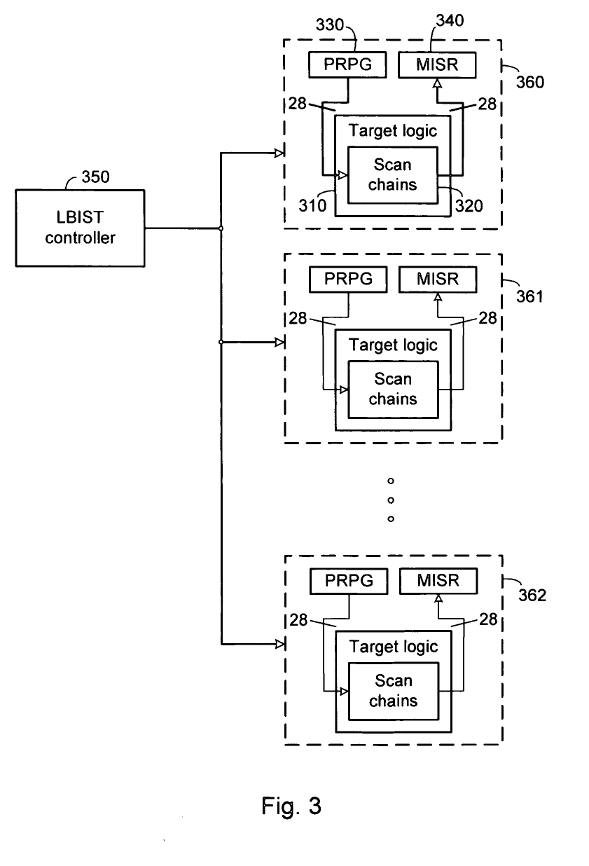

Referring to FIG. 3, a functional block diagram illustrating an LBIST satellite architecture in accordance with one embodiment is shown. In this figure, there is a single LBIST controller 350 that is coupled to multiple LBIST satellites 360-362. While the figure explicitly depicts three LBIST satellites, alternative embodiments may have as few as two satellites, or they may have many more satellites.

Each of the LBIST satellites shown in FIG. 3 has a PRPG (e.g., 330,) a MISR (e.g., 340,) and a set of scan chains (e.g., 320.) Although the scan chains (e.g., 320) are shown as a single block within the target logic (e.g., 310,) it should be noted that there are 28 scan chains in each satellite in this embodiment, as indicated by the 28 -bit-wide data paths between the PRPG and the scan chains, and between the scan chains and the MISR.

In this system, LBIST controller 350 controls each of LBIST satellites 360-362. LBIST controller 350 prepares the components of the system for LBIST operation during an initialization phase. During a test phase, LBIST controller 350 provides timing signals to satellites 360-362 to cause each of them to perform one or more test cycles. For the scan shift phase of each test cycle, LBIST controller 350 provides signals to cause the LBIST satellites to scan bit patterns into and out of their respective scan chains. For the functional phase of each test cycle, LBIST controller 350 provides signals to cause the LBIST satellites to propagate the pseudorandom bit scan bit patterns scanned into their scan chains through the corresponding portions of the target logic and capture the resulting bit patterns in the scan chains. During a termination phase, LBIST controller 350 may cause the MISR signature values generated in each of the LBIST satellites to be read out for comparison to values generated by a control device.

Because the scan chains in each LBIST satellite receive bit patterns from a PRPG within the satellite and provide resulting processed bit patterns to a MISR within the satellite, the data paths associated with the scan chains do not vary as much as in a conventional STUMPS LBIST architecture. As a result, fewer latches are needed in the data paths in order to synchronize the scanning of the bit patterns into the scan chains (as well as to synchronize the scanning of the resulting bit patterns out of the scan chains and into the MISR.) Because fewer synchronization latches are needed in the data paths, less space is needed on the chip to implement the LBIST circuitry using the present architecture, as compared to a conventional architecture.

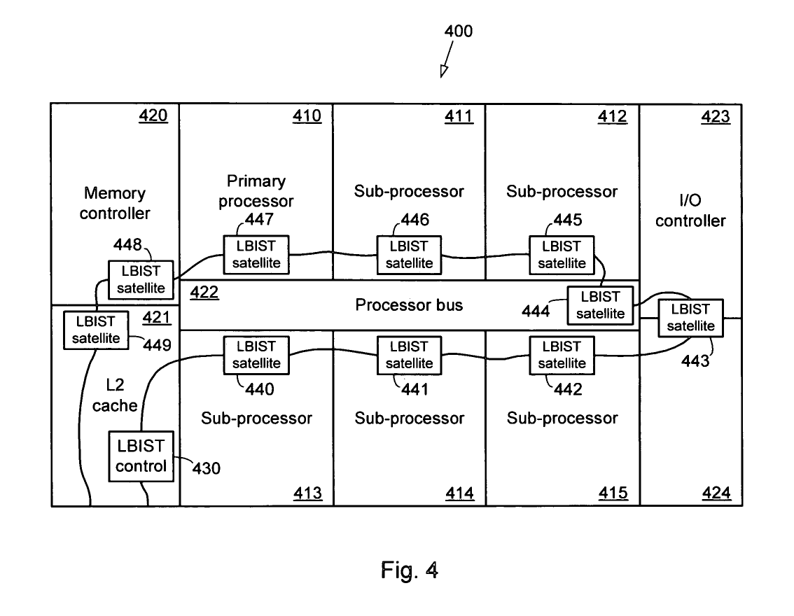

Referring to FIG. 4, a diagram illustrating the positioning of an LBIST controller and LBIST satellites in accordance with one embodiment is shown. Depicted in this figure is a multiprocessor integrated circuit 400.

Integrated circuit 400 includes multiple functional blocks that form the components of the multiprocessor. These functional blocks include a primary processor 410, a set of sub-processor cores (SPCs) 411-415, and a set of components 420-424 that provide support functions. Support components 420-424 may include such things as internal busses, input/output interfaces, cache memories, and the like.

It can be seen in FIG. 4 that the multiprocessor chip includes an LBIST controller 430 and multiple LBIST satellites 440-449. Each of the LBIST satellites is co-located with a corresponding one of the functional blocks of the multiprocessor chip. For example, LBIST satellite 440 is co-located with functional block 413, and satellite 441 is co-located with functional block 414. This is because the various functional blocks of the multiprocessor (410-415 and 420-424) are the target logic that is tested by each of the LBIST satellites. It can be seen that some of the LBIST satellites are co-located with more than one functional block. For instance, LBIST satellite 443 is shown in a position that overlaps with functional blocks 423 and 424. In this case, functional blocks 423 and 424 together form the target logic that is tested by LBIST satellite 443. LBIST controller 430 is not associated with only one of the functional blocks and obviously cannot be co-located with every one of the functional blocks. In this embodiment, LBIST controller 430 is positioned in functional block 421, but this may vary in other embodiments.

It should be noted that “co-located,” as used here, refers to the fact that the components of a particular LBIST satellite are positioned within or near the corresponding functional block. Because the latches of the satellite's scan chains are necessary positioned between the logic gates of the functional block, they are “within” the functional block. The PRPG, MISR and other LBIST satellite components may be positioned within the functional block or outside, but near, the boundaries of the functional block, depending upon the specific layout of the device.

LBIST controller 430 is coupled to each of LBIST satellites 440-449 through control lines. As described above, LBIST controller 430 uses the control lines to provide control signals to LBIST satellites 440-449 and thereby cause the satellites to perform LBIST test cycles. The control lines are not explicitly shown in FIG. 4 for purposes of clarity.

The LBIST system depicted in FIG. 4 includes a control scan chain 450. Control scan chain 450 is used to load and unload data from LBIST controller 430 and LBIST satellites 440-449. In this embodiment, control scan chain 450 comprises scan chain segments that extend from an external input port to LBIST controller 430, from LBIST controller 430 to LBIST satellite 440, and so on. The last segment of control scan chain 450 extends from LBIST satellite 449 to an external output port. Segments of control scan chain 450 may also couple various components within LBIST controller 430 and/or LBIST satellites 440-449. For example, a segment may couple the PRPG of a satellite to the MISR of the satellite, so that the data path of control scan chain 450 enters the satellite, passes through the PRPG, then passes through the MISR and exits the satellite. Other embodiments may, of course, be configured in a different manner.

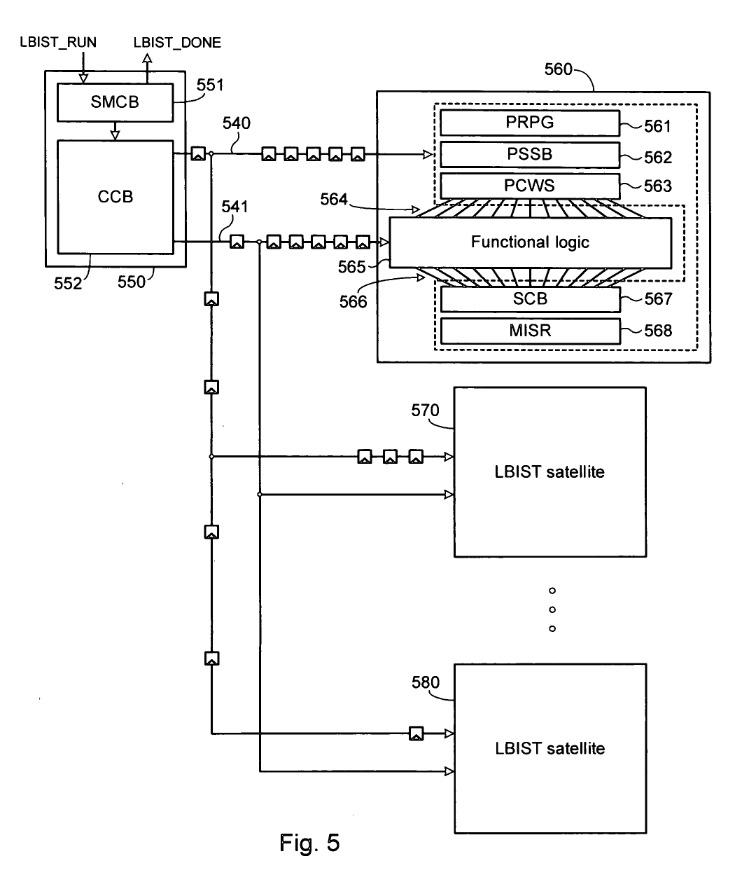

Referring to FIG. 5, a diagram illustrating the structure of the LBIST controller and satellites in more detail in accordance with one embodiment is shown. In this embodiment, LBIST controller 550 includes a state machine control block 551 and a clock control block 552. State machine control block 551 is primarily responsible for starting and stopping the LBIST testing. State machine control block 551 initiates LBIST testing in response to receiving a start signal (LBIST_RUN) from an external source. After testing is complete (e.g., after a predetermined number of test cycles has been completed, or after an error condition has been identified,) state machine control block 551 terminates

LBIST test operations and asserts a termination signal (LBIST_DONE.)

Clock control block 552 is responsible for generating control signals that are provided to the LBIST satellites to enable them to perform LBIST operations. These control signals may be categorized in various ways. For instance, the control signals may be categorized as either satellite control signals or function control signals. Satellite control signals affect such actions as the generation of pseudorandom bit patterns, scanning of the bit patterns into (and out of) the scan chains, and the like. Function control signals affect such actions as the capture of bit patterns that have propagated through the functional logic of the device under test.

In the embodiment of FIG. 5, the satellite control signals are communicated to the LBIST satellites through a set of satellite control lines 540. The function control signals are communicated to the LBIST satellites through a set of function control lines 541. It can be seen that both satellite control lines 540 and function control lines 541 include synchronization latches. As described above, the purpose of the synchronization latches is to delay the control signals on the shorter control lines so that the receipt of the signals by each of the satellites is synchronized. In the embodiment of FIG. 5, it is necessary to insert six latches between LBIST controller 550 and each of the LBIST satellites in order to synchronize the delivery of the control signals.

While only three LBIST satellites (560, 570, 580) are explicitly depicted in FIG. 5, this is for purposes of clarity in the figure, and there may be any number of satellites. In this embodiment, each satellite includes a PRPG (e.g., 561,) a phase shift and spread block (PSSB, e.g., 562,) a programmable channel weight and selector block (PCWS, e.g., 563,) a set of scan chains (e.g., 564/566,) a space compacter block (SCB, e.g., 567) and a MISR (e.g., 568.) While an input end of the scan chains (564) and an output end of the scan chains (566) are shown in the figure, it should be understood that the scan chains extend through the corresponding portions of the functional logic (e.g., 565.)

As described above, the PRPG generates pseudorandom bit patterns to be scanned into the scan chains. In this embodiment, the PRPG utilizes a linear feedback shift register (LFSR) to generate the pseudorandom bit patterns. These bit patterns are then processed by the PSSB to shift the phase of the pseudorandom bit patterns that are shifted into adjacent scan chains. This is done because, even though the bit patterns are pseudorandom, it is common to scan the same pseudorandom bit pattern (shifted by one bit) into adjacent scan chains. The PSSB shifts the patterns by varying numbers of bits to increase the randomness of the bit patterns in adjacent scan chains. The PCWS is designed to allow the pseudorandom bit patterns to be weighted, so that they may contain desired ratios of 1's and 0's, rather than the 50%-50% ratio of a truly (pseudo)random pattern. After the pseudorandom bit patterns generated by the PRPG are processed by the PSSB and PCWS, they are scanned into the scan chains according to the satellite control signals.

After the processed pseudorandom bit patterns are shifted into the scan chains, they are allowed to propagate from the scan chains through the functional logic. The resulting bit patterns produced by the functional logic are captured in the scan chains that follow the functional logic according to the function control signals. The captured signals are scanned out of the scan chains at the same time new bit patterns are scanned into the scan chains. The bit patterns scanned out of the scan chains are processed in this embodiment by a space compactor block (SCB, e.g., 567,) which is configured to reduce the number of bits that have to be processed by MISR 568. This may be accomplished, for example, by XOR′ing the bits received from pairs of adjacent scan chains to reduce the number of bits by a factor of 2. The compacted bits are passed to the MISR, which combines them with the current MISR signature to generate a new MISR signature.

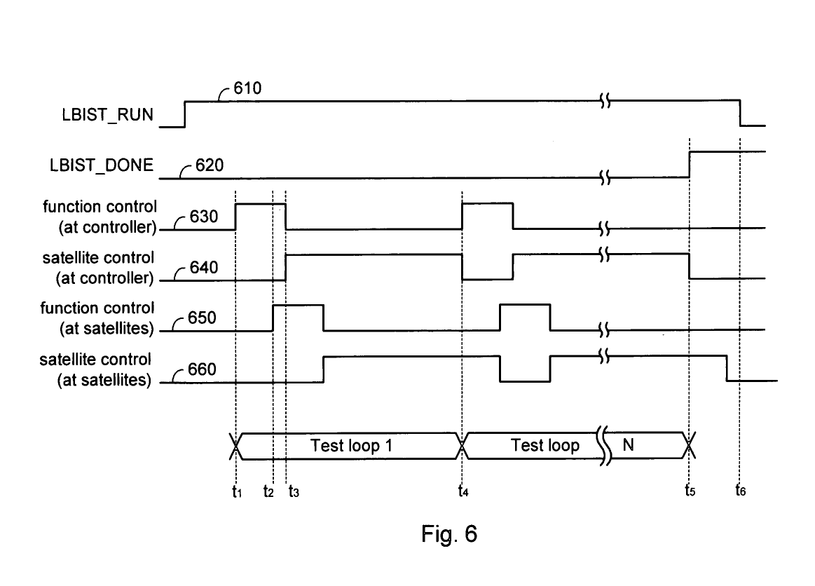

Referring to FIG. 6, a timing diagram illustrating the delay between the generation of control signals by the LBIST controller and the receipt of the signals by the LBIST satellites in accordance with the embodiment of FIG. 5 is shown. In this embodiment, each of the control lines (the satellite control line and the function control line) includes six latches between the LBIST controller and each LBIST satellite. Consequently, it takes six cycles for each of the control signals generated by the LBIST controller to reach the LBIST satellites.

As described above, the signals generated by the LBIST controller include satellite control signals and function control signals. Although these control signals may include various different signals, such as clock signals scan data into the scan chains, each group of control signals is represented in FIG. 6 by a satellite/function control signal that indicates whether the corresponding group of signals is active or not. That is, if the control signal in the figure is high, the corresponding signals are active. For instance, if the satellite control signal is high in the figure, a scan shift clock signal, as well as control signals to the scan chains, will be active, so that data is scanned into the scan chains.

Referring again to FIG. 6, the LBIST controller receives a signal (LBIST_RUN) 610 that causes the controller to initiate LBIST testing. After the LBIST circuitry is initialized, a first LBIST test cycle is initiated at time t1 with the function control signals 640 becoming active. At time t3, function control signals 640 become inactive, and satellite control signals 630 become active. At time t4, satellite control signals 630 become active. This completes a first LBIST cycle. At the end of this test cycle, another test cycle is performed, and the process continues, typically for a predetermined number of test cycles. Upon completion of the last test cycle to (at t5 in this example,) a completion signal (LBIST_DONE) 620 is asserted to indicate that all of the test cycles have been completed. Thereafter, at time t6, signal 610 is deasserted.

It can be seen in FIG. 6 that the control signals received by each LBIST satellite (650, 660) are the same signals produced at the output of the LBIST controller (630, 640.) The only difference between the generated control signals and that received control signals is that the signals received by the LBIST satellites are delayed by six cycles from the time they appear at the output of the LBIST controller. Thus, with respect to the first test cycle, function control signals 660 become active at time t2, which is six cycles later than t1. It should be noted that the magnitude of the delay may vary in alternative embodiments. In embodiments in which the LBIST satellites are all relatively close to the LBIST controller, fewer latches may be required in the control lines. In embodiments in which the LBIST satellites are farther from the LBIST controller, more latches may be required.

While the foregoing description presents several specific exemplary embodiments, there may be many variations of the described features and components in alternative embodiments. For example, the LBIST controller described above may be used to control the LBIST circuitry in both a device under test and a good device, or a separate LBIST controller may be used in conjunction with each of the devices. If separate LBIST controllers are used, it may be necessary in some embodiments to synchronize the test cycles so that the data generated in each test cycle can be properly compared. Many other variations will also be apparent to persons of skill in the art of the invention upon reading the present disclosure.

Those of skill in the art will understand that information and signals may be represented using any of a variety of different technologies and techniques. For example, data, instructions, commands, information, signals, bits, and symbols that may be referenced throughout the above description may be represented by voltages, currents, electromagnetic waves, magnetic fields or particles, optical fields or particles, or any combination thereof. The information and signals may be communicated between components of the disclosed systems using any suitable transport media, including wires, metallic traces, vias, optical fibers, and the like.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Those of skill in the art may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with application specific integrated circuits (ASICs), field programmable gate arrays (FPGAs), general purpose processors, digital signal processors (DSPs) or other logic devices, discrete gates or transistor logic, discrete hardware components, or any combination thereof designed to perform the functions described herein. A general purpose processor may be any conventional processor, controller, microcontroller, state machine or the like. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in software (program instructions) executed by a processor, or in a combination of the two. Software may reside in RAM memory, flash memory, ROM memory, EPROM memory, EEPROM memory, registers, hard disk, a removable disk, a CD-ROM, or any other form of storage medium known in the art. Such a storage medium containing program instructions that embody one of the present methods is itself an alternative embodiment of the invention. One exemplary storage medium may be coupled to a processor, such that the processor can read information from, and write information to, the storage medium. In the alternative, the storage medium may be integral to the processor. The processor and the storage medium may reside, for example, in an ASIC. The ASIC may reside in a user terminal. The processor and the storage medium may alternatively reside as discrete components in a user terminal or other device.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein and recited within the following claims.

What is claimed is:

1. A system comprising:
two or more LBIST satellites, wherein each of the LBIST satellites is configured to perform LBIST testing on a different portion of functional logic of a device under test and wherein data paths for bit patterns processed by each LBIST satellite are contained within the LBIST satellite; and
a common LBIST controller coupled to each of the LBIST satellites, wherein the LBIST controller is configured to provide control signals to each of the satellites.

2. The system of claim 1, wherein the two or more LBIST satellites are implemented in an integrated circuit.

3. The system of claim 1, wherein each LBIST satellite is co-located with a different functional block of a device under test.

4. The system of claim 3, wherein the device under test comprises a multiprocessor integrated circuit, and wherein each of a plurality of processor cores within the multiprocessor integrated circuit has a corresponding LBIST satellite integrated therein.

5. The system of claim 1, wherein the common LBIST controller is coupled to each of the LBIST satellites by corresponding control lines, wherein each of the control lines includes an identical number of synchronization latches.

6. The system of claim 5, wherein the common LBIST controller is coupled to each LBIST satellite by a corresponding satellite control line and a corresponding function control line, wherein the satellite control line is configured to convey satellite control signals that control scanning and processing of data by LBIST circuitry within the LBIST satellite, and wherein the function control line is configured to convey function control signals that control capture of data in scan chains that has propagated through the functional logic corresponding to the LBIST satellite.

7. The system of claim 1, further comprising a control scan chain that is coupled to each of the LBIST satellites and configured to scan data into and out of the LBIST satellites.

8. The system of claim 7, wherein the control scan chain is configured to scan initialization data into the LBIST satellites and scan MISR values out of the LBIST satellites.

9. The system of claim 1, wherein each LBIST satellite includes:
a plurality of scan chains interposed with the portion of functional logic corresponding to the LBIST satellite;
a pseudorandom pattern generator (PRPG) configured to generate pseudorandom bit patterns and to provide the pseudorandom bit patterns to the scan chains; and
a multiple-input signature register (MISR) configured to receive processed bit patterns from the scan chains and to generate a signature value based upon the received processed bit patterns.

10. The system of claim 9, wherein each LBIST satellite further includes:
a phase shift and spread block (PSSB) configured to receive pseudorandom bit patterns from the PRPG and to introduce desired phase shifts into the pseudorandom bit patterns;
a programmable channel weight and selector block (PCWS) continued to receive pseudorandom bit patterns from the PSSB and to select and/or weight the pseudorandom bit patterns for each scan chain; and
a space compactor block (SCB) configured to receive the processed bit patterns from the scan chains and to compact the bit patterns before providing the compacted bit patterns to the MISR.

11. A method comprising:
generating LBIST control signals in an LBIST controller;
conveying the LBIST control signals from the LBIST controller to a plurality of LBIST satellites; and
each of the LBIST satellites performing LBIST testing according to the LBIST control signals.

12. The method of claim 11, wherein each LBIST satellite performing LBIST testing comprises generating pseudorandom bit patterns, propagating the pseudorandom bit patterns through functional logic associated with the LBIST satellite to produce processed bit patterns, and generating signature values from the processed bit patterns.

13. The method of claim 12, further comprising:
phase shifting and spreading the pseudorandom bit patterns among a plurality of scan chains in each LBIST satellite;
selecting and weighting the pseudorandom bit patterns for each scan chain; and
compact the processed bit patterns before generating signature values from the processed bit patterns.

14. The method of claim 11, further comprising co-locating each LBIST satellite with a different functional block of a device under test.

15. The method of claim 14, wherein the device under test comprises a multiprocessor integrated circuit, and the method further comprises co-locating one of the LBIST satellites in each of a plurality of processor cores within the multiprocessor integrated circuit.

16. The method of claim 11, further comprising synchronizing delivery of the control signals to each of the LBIST satellites.

17. The method of claim 16, wherein synchronizing delivery of the control signals to each of the LBIST satellites comprises successively storing the control signals in a series of synchronization latches located in each of a plurality of control paths between the LBIST controller and corresponding ones of the LBIST satellites.

18. The method of claim 17, wherein storing the control signals in a series of synchronization latches comprises storing control signals in each control path in an identical number of synchronization latches.

19. The method of claim 11, further comprising providing a control scan chain that is coupled to each of the LBIST satellites, wherein the method further comprises scanning data into and out of the LBIST satellites.

20. The method of claim 19, wherein scanning data into and out of the LBIST satellites comprises scanning initialization data into the LBIST satellites and scanning MISR values out of the LBIST satellites.
